(19) United States
(12) Patent Application Publication
(10) Pub. No.: US 2016/0247765 A1
(43) Pub. Date: Aug. 25, 2016

(54) SEMICONDUCTOR DEVICE, PLATING METHOD, PLATING SYSTEM AND RECORDING MEDIUM

(71) Applicant: Tokyo Electron Limited, Tokyo (JP)

(72) Inventors: Yuichiro Inatomi, Nirasaki City (JP); Takashi Tanaka, Nirasaki City (JP); Nobutaka Mizutani, Nirasaki City, (JP); Yusuke Saito, Koshi City (JP); Kazutoshi Iwai, Nirasaki City (JP); Mitsuaki Iwashita, Nirasaki City (JP)

(21) Appl. No.: 15/047,710

(22) Filed: Feb. 19, 2016

(30) Foreign Application Priority Data
Feb. 23, 2015 (JP) 2015-033354

(51) Int. Cl. H01L 23/532; C23C 18/16; H01L 21/67; H01L 21/288; H01L 21/768

(52) U.S. Cl. CPC H01L 23/53238; H01L 21/288; H01L 21/76874; H01L 21/76846; H01L 21/67098; C23C 18/1628; C23C 18/1692

(57) ABSTRACT

Adhesivity between a catalyst adsorption layer on a substrate and a barrier metal plating layer can be improved. The catalyst adsorption layer 22 containing a catalyst metal is formed on the substrate 2 by supplying a catalyst solution onto the substrate 2, and a bonding metal layer 22A containing a bonding metal different from the catalyst metal is formed on the catalyst adsorption layer 22 by performing a plating process with the catalyst metal as a catalyst. A barrier metal plating layer 23 is formed on the bonding metal layer 22A by performing a plating process with the bonding metal as a catalyst.

### CROSS-REFERENCE TO RELATED APPLICATION

This application claims the benefit of Japanese Patent Application No. 2015-033354 filed on Feb. 23, 2015, the entire disclosures of which are incorporated herein by reference.

### TECHNICAL FIELD

The embodiments described herein pertain generally to a semiconductor device, a plating method and a plating system of performing a plating process on a substrate, and a recording medium therefor.

### BACKGROUND

Recently, semiconductor devices such as a LSI or the like have been required to have higher density in order to meet requirements for reducing the mounting space or for improving the processing rate. As an example of a technology that achieves the high density, there has been known a multilayer wiring technology of manufacturing a multilayer substrate, such as a three-dimensional LSI or the like, by stacking multiple wiring substrates.

According to the multilayer wiring technology, a through-via-hole, which penetrates the wiring substrate and in which a conductive material such as copper (Cu) is buried, is typically formed in the wiring substrate in order to obtain electrical connection between the wiring substrates. As an example of a technology for forming the through-via-hole in which a conductive material is buried, there has been known an electroless plating method.

As a specific method of producing a wiring substrate, there is known a method in which a substrate having a recess is prepared, a barrier film is formed as a Cu diffusion barrier film within the recess of the substrate, and a seed film is formed on the barrier film by electroless Cu plating. Thereafter, Cu is buried in the recess by electrolytic Cu plating, and the substrate in which the Cu is buried is then thinned by a polishing method such as chemical mechanical polishing. Through this process, a wiring substrate having a through-via-hole in which the Cu is buried is manufactured.

To form the barrier film of the aforementioned wiring substrate, by adsorbing a catalyst metal such as nano-palladium (n-Pd) onto the substrate in advance, a catalyst adsorption layer is formed. Further, by performing a plating process on the catalyst adsorption layer, a barrier film formed of, for example, Co—W—B layers is obtained.

However, in case of forming the barrier film formed of the Co—W—B layers directly on the catalyst adsorption layer containing the catalyst metal such as the n-Pd, there is a problem that the barrier film is peeled off from the catalyst adsorption layer.

Patent Document 1: Japanese Patent Laid-open Publication No. 2010-185113

### SUMMARY

In view of the foregoing, exemplary embodiments provide a semiconductor device, a plating method and a plating system of suppressing a barrier film from being peeled off from a catalyst adsorption layer formed on a substrate, and a recording medium therefor.

In one exemplary embodiment, a semiconductor device includes a substrate; a catalyst adsorption layer, formed on the substrate, containing a catalyst metal adsorbed onto the substrate; a bonding metal layer which is formed on the catalyst adsorption layer by performing a plating process with the catalyst metal as a catalyst and contains a bonding metal different from the catalyst metal; and a barrier metal plating layer formed on the bonding metal layer by performing a plating process with the bonding metal as a catalyst.

In another exemplary embodiment, a plating method of performing a plating process on a substrate includes preparing the substrate; forming a catalyst adsorption layer on the substrate by supplying a catalyst solution containing a catalyst metal onto the substrate; forming a bonding metal layer on the catalyst adsorption layer by supplying a bonding metal solution containing a bonding metal onto the substrate and by performing a plating process with the catalyst metal as a catalyst; and forming a barrier metal plating layer on the bonding metal layer by supplying a barrier metal plating liquid onto the substrate and by performing a plating process with the bonding metal as a catalyst.

In still another exemplary embodiment, a plating system of performing a plating process on a substrate includes a catalyst adsorption layer forming unit configured to form a catalyst adsorption layer on the substrate by supplying a catalyst solution containing a catalyst metal onto the substrate; a bonding metal layer forming unit configured to form a bonding metal layer on the catalyst adsorption layer by supplying a bonding metal solution containing a bonding metal onto the substrate and by performing a plating process with the catalyst metal as a catalyst; and a plating layer forming unit configured to form a barrier metal plating layer on the bonding metal layer by supplying a barrier metal plating liquid onto the substrate and by performing a plating process with the bonding metal as a catalyst.

In yet another exemplary embodiment, there is provided a computer-readable recording medium having stored thereon computer-executable instructions that, in response to execution, cause a plating system to perform a plating method. Here, the plating method includes preparing the substrate; forming a catalyst adsorption layer on the substrate by supplying a catalyst solution containing a catalyst metal onto the substrate; forming a bonding metal layer on the catalyst adsorption layer by supplying a bonding metal solution containing a bonding metal onto the substrate and by performing a plating process with the catalyst metal as a catalyst; and forming a barrier metal plating layer on the bonding metal layer by supplying a barrier metal plating liquid onto the substrate and by performing a plating process with the bonding metal as a catalyst.

According to the exemplary embodiments, the barrier metal plating layer is not peeled off from the catalyst adsorption layer formed on the substrate. Thus, a high-precision semiconductor device can be obtained.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a block diagram illustrating a plating system according to an exemplary embodiment;

FIG. 2 is a flowchart for describing a plating method according to the exemplary embodiment;

FIG. 3A to FIG. 3F are diagrams illustrating a substrate on which the plating method according to the exemplary embodiment is performed;

FIG. 4 is a side cross sectional view illustrating a plating layer forming unit;

FIG. 5 is a plan view illustrating the plating layer forming unit; and

FIG. 6 is a side cross sectional view illustrating a plating layer baking unit.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

<Plating System>

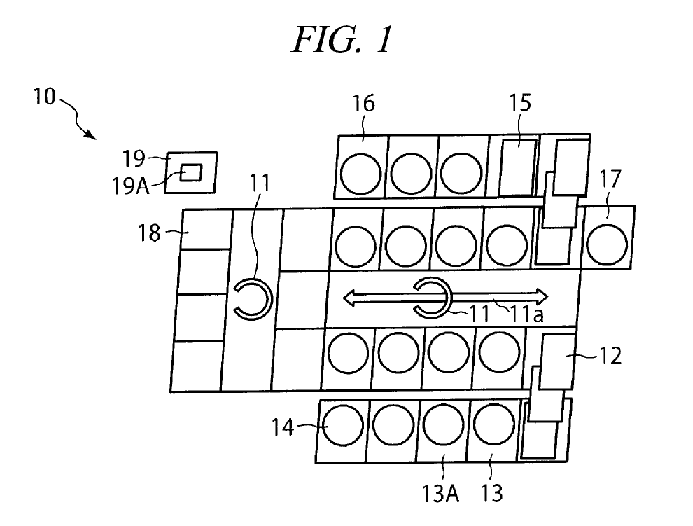

Referring to FIG. 1 to FIG. 6, an exemplary embodiment will be described.

First, a plating system according to the exemplary embodiment will be elaborated with reference to FIG. 1.

As depicted in FIG. 1, the plating system 10 is configured to perform a plating process on a substrate (silicon substrate) 2, such as a semiconductor wafer, having a recess 2a.

The plating system 10 includes a cassette station 18 configured to mount thereon a cassette (not shown) which accommodates the substrate 2 therein; a substrate transfer arm 11 configured to take out the substrate 2 from the cassette on the cassette station 18 and transfer the substrate 2; and a moving path 11a along which the substrate transfer arm 11 is moved.

Further, arranged at one side of the moving path 11a are an adhesion layer forming unit 12 configured to form an adhesion layer 21 to be described later by adsorbing a coupling agent such as a silane coupling agent onto the substrate 2; a catalyst adsorption layer forming unit 13 configured to form a catalyst adsorption layer 22 to be described later by adsorbing a catalyst metal onto the adhesion layer 21 of the substrate 2; a bonding metal layer forming unit 13A configured to form a bonding metal layer 22A containing a bonding metal, which is different from the catalyst metal, on the catalyst adsorption layer 22 by performing a plating process with the catalyst metal as a catalyst; and a plating layer forming unit 14 configured to form a barrier metal plating layer 23 serving as a Cu diffusion barrier film (barrier layer) to be described later on the bonding metal layer 22A of the substrate 2 with the bonding metal as a catalyst.

Further, arranged at the other side of the moving path 11a are a baking unit 15 configured to bake the bonding metal layer 22A and the barrier metal plating layer 23 formed on the substrate 2; and an electroless Cu plating layer forming unit 16 configured to form an electroless copper (Cu) plating layer 24, serving as a seed film to be described later, on the barrier metal plating layer 23 formed on the substrate 2.

Further, an electrolytic Cu plating layer forming unit 17 configured to fill the recess 2a of the substrate 2 with an electrolytic copper (Cu) plating layer 25 while using the electroless Cu plating layer 24 as a seed film is provided adjacent to the baking unit 15.

Further, the respective constituent components of the above-described plating system, for example, the cassette station 18, the substrate transfer arm 11, the adhesion layer forming unit 12, the catalyst adsorption layer forming unit 13, the bonding metal layer forming unit 13A, the plating layer forming unit 14, the baking unit 15, the electroless Cu plating layer forming unit 16 and the electrolytic Cu plating layer forming unit 17 are controlled by a controller 19 according to various types of programs recorded in a recording medium 19A provided in the controller 19, so that various processes are performed on the substrate 2. Here, the recording medium 19A stores thereon various kinds of setup data or various kinds of programs such as a plating processing program to be described later. The recording medium 19A may be implemented by a computer-readable memory such as a ROM or a RAM, or a disk-type recording medium such as a hard disk, a CD-ROM, a DVD-ROM or a flexible disk, as commonly known in the art.

Now, the bonding metal layer forming unit 13A configured to form the bonding metal layer 22A, the plating layer forming unit 14 configured to form the barrier metal plating layer 23 serving as the Cu diffusion barrier film (barrier film), the baking unit 15 and the electroless Cu plating layer forming unit 16 will be further elaborated.

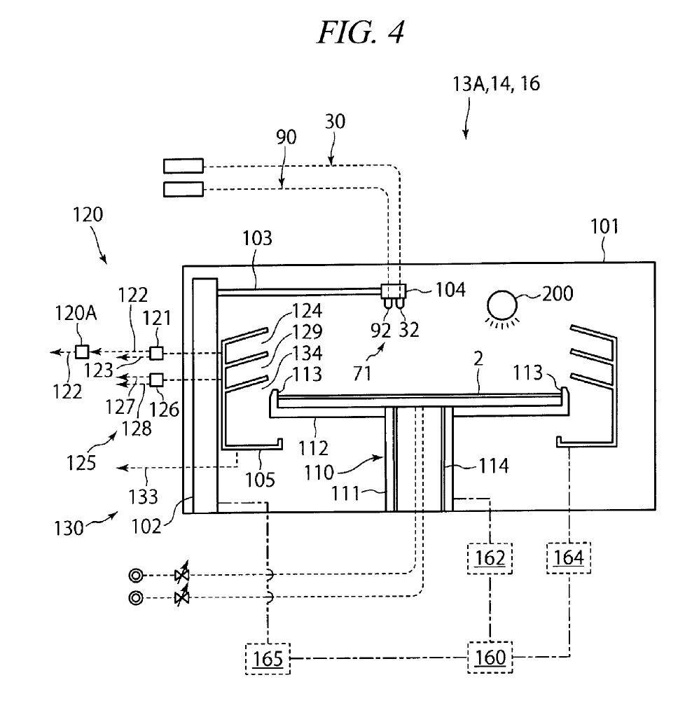

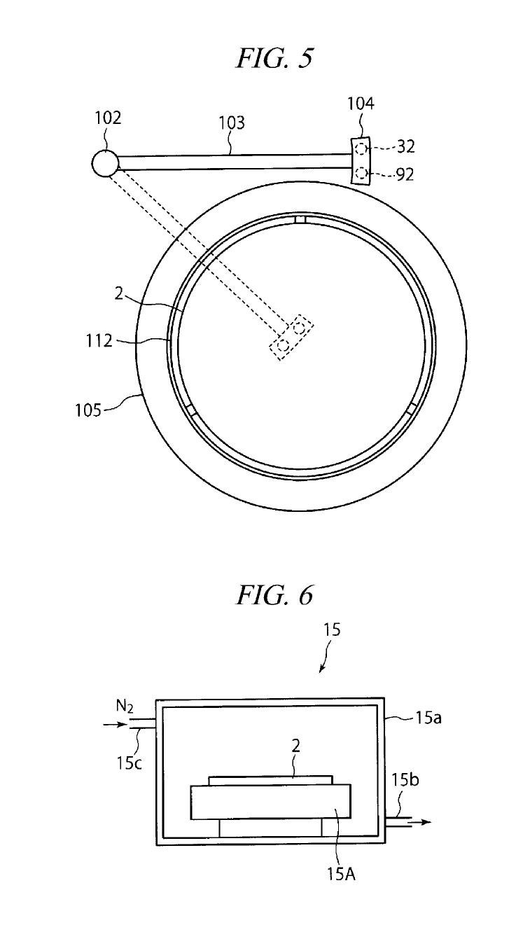

Among these, each of the bonding metal layer forming unit 13A, the plating layer forming unit 14 and the electroless Cu plating layer forming unit 16 may be implemented by a plating apparatus illustrated in FIG. 4 and FIG. 5.

These plating apparatuses 13A, 14 and 16 are illustrated in FIG. 4 and FIG. 5.

That is, each of the plating apparatuses 13A, 14 and 16 includes, as shown in FIG. 4 and FIG. 5, a substrate holding/rotating device (substrate accommodating unit) 110 configured to hold and rotate the substrate 2 within a casing 101; liquid supplying devices 30 and 90 configured to supply a plating liquid, a cleaning liquid or the like onto a surface of the substrate 2; a recovery cup 105 configured to collect the plating liquid, the cleaning liquid or the like dispersed from the substrate 2; draining openings 124, 129 and 134 configured to drain the plating liquid or the cleaning liquid collected by the recovery cup 105; liquid draining devices 120, 125 and 130 configured to drain the liquids collected in the draining openings; and a controller 160 configured to control the substrate holding/rotating device 110, the liquid supplying devices 30 and 90, the recovery cup 105 and the liquid draining devices 120, 125 and 130.

(Substrate Holding/Rotating Device)

The substrate holding/rotating device 110 includes, as illustrated in FIG. 4 and FIG. 5, a hollow cylindrical rotation shaft 111 vertically extended within the casing 101; a turntable 112 provided on an upper end portion of the rotation shaft 111; a wafer chuck 113 disposed on a peripheral portion of a top surface of the turntable 112 to support the substrate 2; and a rotating device 162 configured to rotate the rotation shaft 111. The rotating device 162 is controlled by the controller 160, and the rotation shaft 111 is rotated by the rotating device 162. As a result, the substrate 2 supported on the wafer chuck 113 is rotated.

(Liquid Supplying Device)

Now, the liquid supplying devices 30 and 90 configured to supply a plating solution, a cleaning liquid, or the like onto the surface of the substrate 2 will be explained with reference to FIG. 4 and FIG. 5. The liquid supplying device 30 is a plating liquid supplying device configured to supply a plating liquid onto the surface of the substrate 2. The liquid supplying device 90 is a cleaning liquid supplying device configured to supply a cleaning liquid onto the surface of the substrate 2.

Further, as depicted in FIG. 4 and FIG. 5, a discharge nozzle 32 is provided at a nozzle head 104. The nozzle head 104 is provided at a tip end portion of an arm 103. The arm 103 is provided at a supporting shaft 102 which is rotated by a rotating device 165 and can be moved in a vertical direction. With this configuration, it is possible to discharge the plating liquid onto a target position on the surface of the substrate 2 through the discharge nozzle 32 from a required supply height.

(Cleaning Liquid Supplying Device 90)

The cleaning liquid supplying device 90 is configured to perform a cleaning process on the substrate 2 as will be described later. As illustrated in FIG. 4, the cleaning liquid supplying device 90 includes a nozzle 92 provided at the nozzle head 104. In this configuration, either a cleaning liquid or a rinse liquid is selectively discharged onto the surface of the substrate 2 from the nozzle 92.

(Liquid Draining Device)

Now, the liquid draining devices 120, 125 and 130 configured to drain out the plating liquid or the cleaning liquid dispersed from the substrate 2 will be elaborated with reference to FIG. 4. As shown in FIG. 4, the recovery cup 105, which can be moved up and down by an elevating device 164 and has the draining openings 124, 129 and 134, is disposed within the casing 101. The liquid draining devices 120, 125 and 130 are configured to drain out the liquids collected in the draining openings 124, 129 and 134, respectively.

As depicted in FIG. 4, the plating liquid draining devices 120 and 125 include collecting flow paths 122 and 127 and waste flow paths 123 and 128, which are switchably connected by flow path switching devices 121 and 126, respectively. Here, the plating liquid are collected and reused through the collecting flow paths 122 and 127, respectively, and the plating liquid are drained out through the waste flow paths 123 and 128, respectively. Further, as shown in FIG. 4, the processing liquid draining device 130 is only equipped with a waste flow path 133.

Further, as depicted in FIG. 4, the collecting flow path 122 of the plating liquid draining device 120 configured to drain the plating liquid is connected to an outlet side of the substrate accommodating unit 110, and a cooling buffer 120A configured to cool the plating liquid is provided at a portion of the collecting flow path 122 in the vicinity of the outlet side of the substrate accommodating unit 110.

Now, the baking unit 15 will be elaborated.

The baking unit 15 includes, as illustrated in FIG. 6, an airtightly sealed casing 15a; and a hot plate 15A provided within the airtightly sealed casing 15a.

The airtightly sealed casing 15a of the baking unit 15 is provided with a transfer opening (not shown) through which the substrate 2 is transferred. An N₂ gas is supplied into the airtightly sealed casing 15a through an N₂ gas supply opening 15c.

Further, by evacuating the inside of the airtightly sealed casing 15a through an exhaust opening 15b and filling the inside of the airtighly sealed casing 15a with the N₂ gas, the inside of the airtightly sealed casing 15a can be maintained under an inert gas atmosphere.

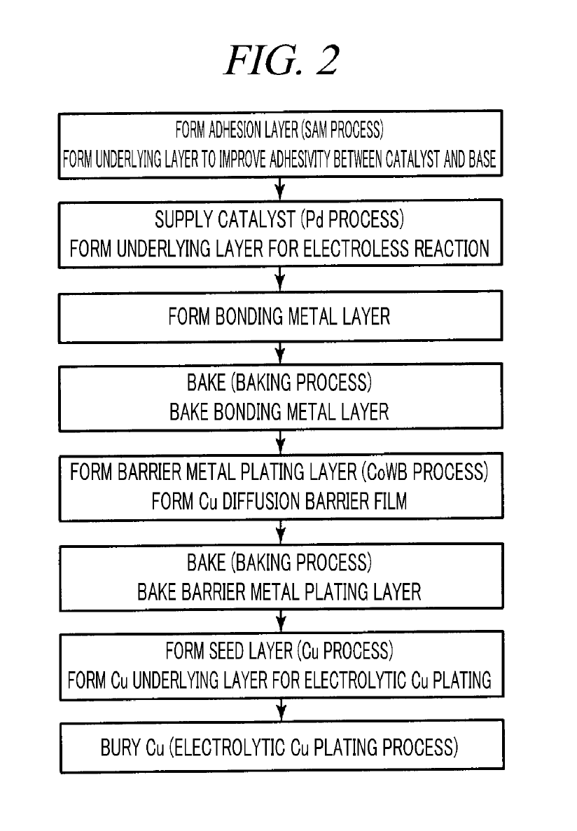

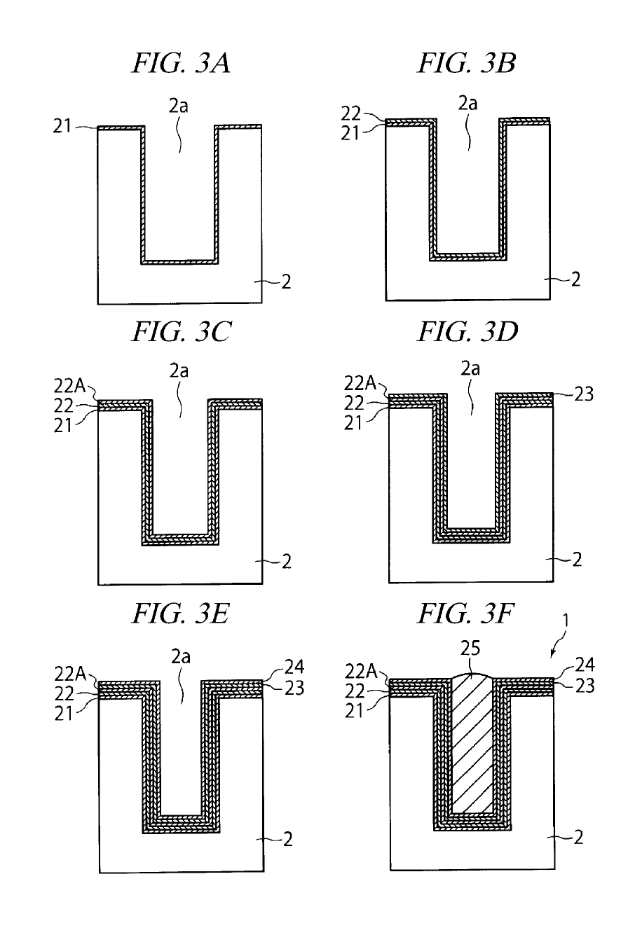

Now, an operation of the plating system according to the exemplary embodiment having the above-described configuration will be explained with reference to FIG. 2 and FIG. 3A to FIG. 3F.

First, in a pre-process, a recess 2a is formed on a substrate (silicon substrate) 2 such as a semiconductor wafer or the like. The substrate 2 having thereon the recess 2a is then transferred into the plating system 10 according to the exemplary embodiment.

Within the adhesion layer forming unit 12 of the plating system 10, an adhesion layer 21 is formed on the substrate 2 having the recess 2a (see FIG. 2 and FIG. 3A).

Here, as a method of forming the recess 2a on the substrate 2, a commonly known method in the art may be appropriately employed. Specifically, as a dry etching technique, for example, a general-purpose technique using a fluorine-based gas or a chlorine-based gas may be employed. Especially, in order to form a hole having a high aspect ratio (hole depth/hole diameter), a method using an ICP-RIE (Inductively Coupled Plasma Reactive Ion Etching) technique, which can perform a deep etching process with a high speed, may be more appropriately adopted. Especially, a Bosch process in which an etching process using sulfur hexafluoride (SF₆) and a protection process using a Teflon-based gas such as C₄F₈ are repeatedly performed may be appropriately utilized.

Further, the adhesion layer forming unit 12 has a decompression chamber (not shown) equipped with a heating unit. Within the adhesion layer forming unit 12, a coupling agent such as a silane coupling agent is adsorbed onto the substrate 2 having the recess 2a, so that the adhesion layer 21 is formed on the substrate 2 (SAM process). The adhesion layer 21 formed by adsorbing the silane coupling agent is configured to improve adhesivity between the substrate 2 and a catalyst adsorption layer 22 to be described later.

The substrate 2 on which the adhesion layer 21 is formed in the adhesion layer forming unit 12 is then transferred by the substrate transfer arm 11 into the catalyst adsorption layer forming unit 13. In the catalyst adsorption layer forming unit 13, a catalyst solution containing a catalyst metal is supplied onto the substrate 2, and the catalyst metal is adsorbed onto the adhesion layer 21, so that the catalyst adsorption layer 22 is formed (see FIG. 3B).

Next, the catalyst solution supplied to the substrate 2 and the catalyst metal contained in the catalyst solution will be explained. First, the catalyst metal will be elaborated.

As the catalyst metal adsorbed onto the adhesion layer 21 of the substrate 2, a catalyst having catalysis to accelerate a plating reaction may be appropriately used. By way of example, a catalyst metal formed of nanoparticles may be used. Here, the nanoparticle means a colloid particle that has catalysis and has an average particle diameter equal to or smaller than 20 nm, e.g., within the range from 0.5 nm to 20 nm. An element constituting the nanoparticles may include, by way of example, but not limitation, palladium, gold, platinum, or the like. Among these, the palladium of nanoparticle may be represented as n-Pd.

Further, as the element constituting the nanoparticles, ruthenium may be used.

A method of measuring the average particle diameter of the nanoparticles is not particularly limited, and various methods may be adopted. By way of example, when measuring the average particle diameter of the nanoparticles in the catalyst solution, a dynamic light scattering method may be employed. In the dynamic light scattering method, a laser beam is irradiated to the nanoparticles dispersed in the catalyst solution, and the average particle diameter of the nanoparticles is calculated by measuring scattered light.

Further, to measure the average particle diameter of the nanoparticles adsorbed on the recess 2a of the substrate 2, a preset number of nanoparticles, for example, twenty nanoparticles may be detected from an image which is obtained by using a TEM (Transmission Electron Microscope) or a SEM (Scanning Electron Microscope), and the average particle diameter of these nanoparticles may be calculated.

Now, the catalyst solution containing the catalyst formed of the nanoparticles will be elaborated. The catalyst solution contains ions of a metal constituting the nanoparticles serving as the catalyst. For example, if palladium constitutes the nanoparticles, the catalyst solution contains a palladium compound, such as palladium chloride, as a palladium ion source.

A specific composition of the catalyst solution is not particularly limited. Desirably, however, the composition of the catalyst solution is set such that the catalyst solution has a viscosity coefficient equal to or less than 0.01 Pa·s. By setting the viscosity coefficient of the catalyst solution to be in this range, the catalyst solution can be sufficiently diffused down up to a bottom portion of the recess 2a of the substrate 2, even if a diameter of the recess 2a of the substrate 2 is small. Accordingly, the catalyst metal can be securely adsorbed to the bottom portion of the recess 2a of the substrate 2 as well more securely.

Desirably, the catalyst metal in the catalyst solution is coated with a dispersant. Accordingly, surface energy of the catalyst metal can be reduced. As a result, it is assumed that the diffusion of the catalyst metal within the catalyst solution can be more accelerated, so that the catalyst metal can reach the bottom portion of the recess 2a of the substrate 2 in a shorter time period.

Furthermore, it is assumed that an increase in the diameter of the catalyst metal caused by agglomeration of multiple catalyst metals can be suppressed, so that the diffusion of the catalyst metal in the catalyst solution can be further accelerated.

A method for preparing the catalyst metal coated with the dispersant is not particularly limited. By way of example, a catalyst solution containing the catalyst metal which is previously coated with the dispersant may be supplied to the catalyst adsorption layer forming unit 13. Alternatively, the catalyst adsorption layer forming unit 13 may be configured to perform therein a process of coating the catalyst metal with the dispersant, for example, within the catalyst solution supplying device.

Specifically, it is desirable to use polyvinylpyrrolidone (PVP), polyacrylic acid (PAA), polyethyleneimine (PEI), tetramethylammonium (TMA), citric acid, or the like as the dispersant.

Besides, various chemical materials for controlling the characteristic may be added into the catalyst solution.

Furthermore, the catalyst solution containing the catalyst metal may not be limited to the catalyst solution containing the nanoparticles such as n-Pd. By way of example, an aqueous solution of palladium chloride (PdCl₂) may be used as the catalyst solution, and Pd ions in the palladium chloride (PdCl₂) may be used as the catalyst metal.

After the catalyst adsorption layer 22 is formed on the substrate 2 in the catalyst adsorption layer forming unit 13 as stated above, the substrate 2 is then transferred into the bonding metal layer forming unit 13A by the substrate transfer arm 11.

Then, in the bonding metal layer forming unit 13A, a plating process is performed on the catalyst adsorption layer 22 of the substrate 2 by using the catalyst metal of the catalyst adsorption layer 22 as a catalyst, so that a bonding metal layer 22A containing a bonding metal such as Ni or a Ni alloy (NiB or the like), which is different from the catalyst metal, is formed (see FIG. 3C).

The bonding metal layer forming unit 13A is implemented by the plating apparatus as illustrated in FIG. 4 and FIG. 5. The bonding metal layer 22A is formed by performing an electroless plating process on the catalyst adsorption layer 22 of the substrate 2.

In this case, a thickness of the bonding metal layer 22A is set to form a film where no conspicuous gap is formed between the bonding metals such as NiB or the like. For example, it is desirable that the thickness of the bonding metal layer 22A is set to be in the range form 25 nm to 50 nm.

Subsequently, the substrate 2 having the bonding metal layer 22A formed on the catalyst adsorption layer 22 thereof is transferred from the bonding metal layer forming unit 13A into the airtightly sealed casing 15a of the baking unit 15 by the substrate transfer arm 11. Within the airtightly sealed casing 15a of the baking unit 15, the substrate 2 is heated on a hot plate 15A under an inert gas atmosphere where the N₂ gas is filled, in order to suppress the substrate 2 from being oxidized. Accordingly, the bonding metal layer 22A of the substrate 2 is baked (baking process).

When baking the bonding metal layer 22A in the baking unit 15, a baking temperature may be set to be in the range from, e.g., 150° C. to 200° C., and a baking time is set to be in the range from, e.g., 10 minutes to 30 minutes.

By baking the bonding metal layer 22A on the substrate 2 as described above, moisture within the bonding metal layer 22A can be removed, and, at the same time, the bond between metals within the bonding metal layer 22A can be enhanced.

Then, the substrate 2 is sent to the plating layer forming unit 14 by the substrate transfer arm 11.

Thereafter, in the plating layer forming unit 14, a barrier metal plating layer 23 serving as a Cu diffusion barrier film (barrier film) is formed on the bonding metal layer 22A of the substrate 2 (see FIG. 3D).

Here, the plating layer forming unit 14 is implemented by the plating apparatus as illustrated in FIG. 4 and FIG. 5. By performing an electroless plating process on the bonding metal layer 22A of the substrate 2 with the bonding metal of the bonding metal layer 22A as a catalyst, the barrier metal plating layer 23 can be formed (see FIG. 3D).

When forming the barrier metal plating layer 23 in the plating layer forming unit 14, a plating liquid containing, for example, Co—W—B may be used as the plating liquid, and a temperature of the plating liquid is maintained at 40° C. to 75° C. (desirably, 65° C.).

By supplying the plating liquid containing the Co—W—B onto the substrate 2, the barrier metal plating layer 23 containing the Co—W—B is formed on the bonding metal layer 22A of the substrate 2 by the electroless plating process with the bonding metal of the bonding metal layer 22A as a catalyst. The barrier metal plating layer 23 may have a monolayer structure.

Thereafter, the substrate 2 having the barrier metal plating layer 23 formed on the bonding metal layer 22A thereof is transferred from the plating layer forming unit 14 into the airtightly sealed casing 15a of the baking unit 15 by the substrate transfer arm 11. Within the airtightly sealed casing 15a of the baking unit 15, the substrate 2 is heated on the hot plate 15A under an inert gas atmosphere where the N₂ gas is filled, in order to suppress the substrate 2 from being oxidized. Accordingly, the barrier metal plating layer 23 of the substrate 2 is baked (baking process).

When baking the barrier metal plating layer 23 in the baking unit 15, the baking temperature may be set to be in the range from, e.g., 150° C. to 200° C., and the baking time is set to be in the range from, e.g., 10 minutes to 30 minutes.

By baking the barrier metal plating layer 23 on the substrate 2 as described above, moisture within the barrier metal plating layer 23 can be removed, and, at the same time, the bond between metals within the barrier metal plating layer 23 can be enhanced.

As described above, the barrier metal plating layer 23 can be formed on the bonding metal layer 22A of the substrate 2. As mentioned above, the bonding metal layer 22A has a thickness in the range from 25 nm to 50 nm, and the barrier metal plating layer 23 has a thickness in the range from 250 nm to 500 nm. That is, the thickness of the bonding metal layer 22A is much smaller than the thickness of the barrier metal plating layer 23.

According to the exemplary embodiment, the thin bonding metal layer 22A containing the bonding metal, which is different from the catalyst metal of the catalyst adsorption layer 22, is formed between the catalyst adsorption layer 22 and the barrier metal plating layer 23, so that the bonding metal layer 22A firmly adheres to both the catalyst adsorption layer 22 and the barrier metal plating layer 23. Therefore, as compared to a case where the barrier metal plating layer 23 is directly formed on the catalyst adsorption layer 22, adhesivity between the catalyst adsorption layer 22 and the barrier metal plating layer 23 can be remarkably improved.

The substrate 2 having the barrier metal plating layer 23 formed thereon is sent into the electroless Cu plating layer forming unit 16 by the substrate transfer arm 11.

Subsequently, in the electroless Cu plating layer forming unit 16, an electroless Cu plating layer 24 serving as a seed film for forming an electrolytic Cu plating layer 25 is formed on the barrier metal plating layer 23 of the substrate 2 (see FIG. 3E).

Here, the electroless Cu plating layer forming unit 16 is implemented by the plating apparatus as illustrated in FIG. 4 and FIG. 5. By performing the electroless plating process on the barrier metal plating layer 23 of the substrate 2, the electroless Cu plating layer 24 can be formed.

The electroless Cu plating layer 24 formed in the electroless Cu plating layer forming unit 16 serves as the seed film for forming the electrolytic Cu plating layer 25. A plating liquid used in the electroless Cu plating layer forming unit 16 may contain a copper salt as a source of copper ions, such as copper sulfate, copper nitrate, copper chloride, copper bromide, copper oxide, copper hydroxide, copper pyrophosphate, or the like. The plating liquid may further contain a reducing agent and a complexing agent for the copper ions. Further, the plating liquid may further contain various kinds of additives for improving stability or speed of the plating reaction.

The substrate 2 having the electroless Cu plating layer 24 formed thereon is sent to the electrolytic Cu plating layer forming unit 17 by the substrate transfer arm 11. Here, the substrate 2 having the electroless Cu plating layer 24 formed thereon may be sent to the electrolytic Cu plating layer forming unit 17 after sent to and baked in the baking unit 15. Subsequently, in the electrolytic Cu plating layer forming unit 17, an electrolytic Cu plating process is performed on the substrate 2, so that an electrolytic Cu plating layer 25 is filled within the recess 2a of the substrate 2 by using the electroless Cu plating layer 24 as the seed film (see FIG. 3F). As a result, a semiconductor device 1 having the substrate 2, the adhesion layer 21, the catalyst adsorption layer 22, the bonding metal layer 22A, the barrier metal plating layer 23, the electroless Cu plating layer 24 and the electrolytic Cu plating layer 25 is obtained.

Then, the substrate 2 is taken out of the plating system 10.

According to the exemplary embodiment as described above, since the thin bonding metal layer 22A containing the bonding metal, which is different from the catalyst metal, is formed between the catalyst adsorption layer 22 and the barrier metal plating layer 23, the adhesivity between the catalyst adsorption layer 22 and the barrier metal plating layer 23 can be greatly improved.

### Modification Examples

In addition, the above exemplary embodiment has been described for the case where the electrolytic Cu plating layer is obtained through the electrolytic Cu plating process. However, the exemplary embodiment is not limited thereto, and the Cu plating layer may be formed by performing the electroless Cu plating process instead of the electrolytic Cu plating process.

Moreover, in the above-described exemplary embodiment, to bake the bonding metal layer 22A and the barrier metal plating layer 23, the substrate 2 is heated on the hot plate 15A within the airtightly sealed casing 15a of the baking unit 15 under the inert gas atmosphere where the N₂ gas is filled. However, the exemplary embodiment is not limited thereto. By way of example, to reduce a processing temperature or to shorten a processing time, the substrate 2 may be heated on the hot plate 15A while depressurizing the airtightly sealed casing 15a to the vacuum level.

In addition, in the above-described exemplary embodiment, the baking unit 15 is configured as a separate apparatus from the bonding metal layer forming unit 13A and the plating layer forming unit 14. However, the exemplary embodiment is not limited thereto. For example, a heating source such as a lamp irradiating unit 200 (UV light or the like) arranged above the substrate 2 or a hot plate (not shown) covering the substrate 2 may be provided in the plating layer forming unit 14 shown in FIG. 4, and the bonding metal layer or the plating layer may be baked within the plating layer forming unit 14.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A semiconductor device, comprising:
a substrate;
a catalyst adsorption layer, formed on the substrate, containing a catalyst metal adsorbed onto the substrate;
a bonding metal layer which is formed on the catalyst adsorption layer by performing a plating process with the catalyst metal as a catalyst and contains a bonding metal different from the catalyst metal; and
a barrier metal plating layer formed on the bonding metal layer by performing a plating process with the bonding metal as a catalyst.

2. The semiconductor device of claim 1,
wherein the catalyst metal of the catalyst adsorption layer contains n-Pd or palladium chloride.

3. The semiconductor device of claim 1,
wherein the bonding metal of the bonding metal layer contains Ni or a Ni alloy.

4. The semiconductor device of claim 1,
wherein the barrier metal plating layer contains Co or a Co alloy.

5. The semiconductor device of claim 1,
wherein a thickness of the bonding metal layer is smaller than a thickness of the barrier metal plating layer.

6. The semiconductor device of claim 1,
wherein the barrier metal plating layer has a monolayer structure.

7. A plating method of performing a plating process on a substrate, comprising:
preparing the substrate;
forming a catalyst adsorption layer on the substrate by supplying a catalyst solution containing a catalyst metal onto the substrate;
forming a bonding metal layer on the catalyst adsorption layer by supplying a bonding metal solution containing a bonding metal onto the substrate and by performing a plating process with the catalyst metal as a catalyst; and
forming a barrier metal plating layer on the bonding metal layer by supplying a barrier metal plating liquid onto the substrate and by performing a plating process with the bonding metal as a catalyst.

8. The plating method of claim 7,
wherein the catalyst metal of the catalyst adsorption layer contains n-Pd or palladium chloride.

9. The plating method of claim 7,
wherein the bonding metal of the bonding metal layer contains Ni or a Ni alloy.

10. The plating method of claim 7,
wherein the barrier metal plating layer contains Co or a Co alloy.

11. The plating method of claim 7,
wherein a thickness of the bonding metal layer is smaller than a thickness of the barrier metal plating layer.

12. The plating method of claim 7,
wherein the barrier metal plating layer has a monolayer structure.

13. The plating method of claim 7,
wherein the substrate is baked after the forming of the bonding metal layer.

14. A plating system of performing a plating process on a substrate, comprising:
a catalyst adsorption layer forming unit configured to form a catalyst adsorption layer on the substrate by supplying a catalyst solution containing a catalyst metal onto the substrate;
a bonding metal layer forming unit configured to form a bonding metal layer on the catalyst adsorption layer by supplying a bonding metal solution containing a bonding metal onto the substrate and by performing a plating process with the catalyst metal as a catalyst; and
a plating layer forming unit configured to form a barrier metal plating layer on the bonding metal layer by supplying a barrier metal plating liquid onto the substrate and by performing a plating process with the bonding metal as a catalyst.

15. The plating system of claim 14, further comprising:
a baking unit configured to bake the substrate on which the bonding metal layer is formed.

16. A computer-readable recording medium having stored thereon computer-executable instructions that, in response to execution, cause a plating system to perform a plating method,
wherein the plating method comprises:
preparing the substrate;
forming a catalyst adsorption layer on the substrate by supplying a catalyst solution containing a catalyst metal onto the substrate;
forming a bonding metal layer on the catalyst adsorption layer by supplying a bonding metal solution containing a bonding metal onto the substrate and by performing a plating process with the catalyst metal as a catalyst; and
forming a barrier metal plating layer on the bonding metal layer by supplying a barrier metal plating liquid onto the substrate and by performing a plating process with the bonding metal as a catalyst.
